(19) United States
(12) Patent Application Publication
(10) Pub. No.: US 2012/0313650 A1
(43) Pub. Date: Dec. 13, 2012

(54) INSPECTION DEVICE AND INSPECTION METHOD

(75) Inventors: Hiroshi Kawaguchi, Hitachinaka (JP); Minori Noguchi, Joso (JP); Kenji Aiko, Ninomiya (JP); Masami Makuuchi, Yokohama (JP)

(73) Assignee: HITACHI HIGH-TECHNOLOGIES CORPORATION, Minato-ku, Tokyo (JP)

(21) Appl. No.: 13/580,273

(22) PCT Filed: Dec. 1, 2010
(86) PCT No.: PCT/JP2010/007000

§ 371 Date: Aug. 21, 2012

(30) Foreign Application Priority Data
Mar. 25, 2010 (JP) 2010-069114

(51) Int. Cl. G01R 27/26

(52) U.S. Cl. 324/679

(57) ABSTRACT

An inspection device for detecting small foreign bodies is provided with a first electrode and a second electrode disposed on either side of the inspection target, a power source connected to the aforementioned first electrode, a conveyance speed control unit for controlling the conveyance speed of the aforementioned inspection target, a current detection unit which, connected to the aforementioned second electrode, detects currents generated by changes in the static capacitance formed between the aforementioned first electrode and the aforementioned second electrode, and a defect detection unit which detects defects on the basis of the aforementioned current. Furthermore, the aforementioned second electrode rotates in the direction opposite of the conveyance direction of the aforementioned inspection target. Furthermore, the aforementioned power source includes a DC or an AC power source.

### TECHNICAL FIELD

The present invention relates to an inspection device to detect defects (such as scratches and cracks) and foreign bodies of an object to be inspected. More particularly, it relates to an inspection device and an inspection method for detecting metal defects in planar metals, such as battery sheets.

### BACKGROUND ART

FIG. 1 shows an example of a lithium battery manufacturing process. Raw materials are mixed and kneaded as electrode materials; as for a positive electrode a positive electrode medium such as lithium cobalt oxide is applied to both surfaces of an aluminum foil as shown in FIG. 2(a) and dried and as for a negative electrode a negative electrode medium such as carbon material is applied to both surfaces of a copper foil as shown in FIG. 2(b) and dried.

The dried electrodes are cut and processed so that they are rolled while separator materials such as plastics are stacked with the positive electrode and the negative electrode alternately as shown in FIG. 2(c) and pressed together to increase their density.

After being pressed, they are welded at current collector parts and then assembled with an electrolyte and the like into a cell to be finished as a lithium battery.

Here, in the process of manufacturing a battery with the positive electrode and the negative electrode (hereinafter, these are referred to as battery sheets) as a positive pole and a negative pole respectively, if metallic foreign bodies are mixed in the battery sheets, a problem arises that micro-shorts can occur and a battery performance greatly degrades.

There have been growing expectations in recent years that the lithium batteries will be applied to electric cars, but there are chances that short circuits or the like occur due to metallic foreign bodies.

Therefore, a need to inspect the battery sheets for metallic foreign bodies is growing from the standpoint of improvement in reliability.

As for prior arts associated with an inspection method for foreign bodies in electrode materials of the lithium batteries, a method for detecting existence of foreign bodies by generating magnetic disturbances due to the magneto-impedance effect as described in Patent Literature 1; as for prior arts associated with a defect inspection method in a multilayered metal film there is a method in which a high voltage is applied to the multilayered metal film while delaying the rise time and a current is detected as described in Patent Literature 2.

Also, in Patent Literature 3, disclosed is a method in which an insulating sheet is put between electrodes in a thickness direction and existence of foreign bodies is determined by detecting electric conduction or discharge occurring between a roller electrode and an electrode.

Also in Patent Literature 4, a device is disclosed which inspects damages in a film with an electrostatic capacitance with the film put between a pair of electrodes.

### CITATION LIST

### Patent Literature

Patent Literature 1: JP-A-2005-183142
Patent Literature 2: JP-A-2003-75412
Patent Literature 3: JP-A-2002-243791
Patent Literature 4: JP-A-2002-131833

### SUMMARY OF INVENTION

### Technical Problem

In the method described in Patent Literature 1 there are no alternative ways but to increase the voltage in order to detect smaller foreign bodies, and no consideration is given in an aspect of the inspection object being destroyed by discharge due to high voltage.

Further, in the method described in Patent Literature 2, when a moving speed of a magnetic resistance is increased to detect smaller foreign bodies, it may exceed a response speed of a magneto-impedance sensor and it may become impossible to detect them.

Moreover, Patent Literature 3 has the object to be inspected (insulating sheet) in contact with and put between two electrodes.

However, controlling a feeding speed of the object to be inspected is not disclosed.

Furthermore, Patent Literature 4 forms an electric field by an AC power supply, but it does not disclose the voltage control or the feeding speed control.

### Solution to Problem

The present invention has the following characteristics. Incidentally, the present invention may have any of the characteristics independently or may include those in combinations.

A first characteristic of the present invention lies in comprising: a transfer unit to transfer an object to be inspected; a first electrode and a second electrode arranged to put the object to be inspected therebetween; a power supply connected to the first electrode; a transfer speed control unit to control a transfer speed of the object to be inspected; a current detection unit connected to the second electrode to detect a current generated due to a change in an electrostatic capacitance formed between the first electrode and the second electrode; and a defect detection unit to detect a defect based on the current.

A second characteristic of the present invention lies in the power supply being a DC power supply.

A third characteristic of the present invention lies in comprising a spacing control unit to control a spacing between the first electrode and the second electrode.

A fourth characteristic of the present invention lies in comprising a voltage control unit to control a voltage of the power supply.

A fifth characteristic of the present invention lies in comprising an amplifier unit to amplify the current; and an I-V conversion unit to convert the amplified current into a voltage; wherein the defect detection unit detects a defect based on the converted voltage.

A sixth characteristic of the present invention lies in a plurality of the first electrodes and a plurality of the second electrodes being arranged in a direction parallel to a surface of the object to be inspected.

A seventh characteristic of the present invention lies in the first electrodes and the second electrodes being arranged in a lattice pattern.

An eighth characteristic of the present invention lies in the first electrodes and the second electrodes being arranged in a direction perpendicular to a direction of transfer of the object to be inspected.

A ninth characteristic of the present invention lies in comprising a marking unit to mark a position of a defect.

A tenth characteristic of the present invention lies in comprising a cooling unit to cool the second electrode and the current detection unit.

An eleventh characteristic of the present invention lies in comprising a pair of electrodes arranged parallel to each other with one of the electrodes movable; a detection means connected to one of the electrodes to detect a change in an electrostatic capacitance between the electrodes; and a power supply connected to the other electrode; wherein the object to be inspected disposed between the electrodes and electrically connected to the movable electrode to be at the same potential thereof is controlled in a moving speed in synchronism with a movement of the movable electrode and the power supply is controlled together so that the detection conditions are optimized and existence of a defect on the object to be inspected is detected by converting a current flowing at the time of a change in the electrostatic capacitance between the electrodes into voltage.

A twelfth characteristic of the present invention lies in the second electrode being a rotating electrode that rotates in a direction opposite to a direction in which the object to be inspected is transferred.

A thirteenth characteristic of the present invention lies in a plurality of the rotating electrodes being arranged uniformly or at a certain interval on a rotating body.

A fourteenth characteristic of the present invention lies in the plurality of the rotating electrodes arranged at a certain interval on the rotating body being arranged in a lattice pattern on the rotating body.

A fifteenth characteristic of the present invention lies in the plurality of the rotating electrodes being arranged at a certain interval on the rotating body and rotation start positions or phases of electrode positions of the rotating electrodes being controlled so that a same position on the object to be inspected can be inspected at different phases.

A sixteenth characteristic of the present invention lies in the defect detection unit determining a kind and a size of the defect from a polarity, an output value, and a detection width (or a detection time, in another expression) of a detected signal.

A seventeenth characteristic of the present invention lies in the power supply being an AC power supply.

An eighteenth characteristic of the present invention lies in the current detection unit comprising a voltage detection unit.

A nineteenth characteristic of the present invention lies in a voltage and a cycle of the AC power supply and a resistance of a voltage detection unit being controlled.

A twentieth characteristic of the present invention lies in the defect detection unit determining a kind and a size of the defect from a phase and an output value of a detected signal.

Further, the above processings and controls are performed by one and the same or a plurality of processing units.

### Advantageous Effects of Invention

The present invention has the following advantages. Incidentally, the advantages below may show up independently or may show up simultaneously.

(1) While avoiding possibilities of destruction of objects to be inspected due to discharges that occur by using a high voltage power supply in order to increase detection sensitivity and of high voltage application, enhancement of the sensitivity can be expected.

(2) Since a proportional relationship holds between a moving speed of the object to be inspected and the detection sensitivity, high sensitivity and improved throughput can be designed at the same time.

### BRIEF DESCRIPTION OF DRAWINGS

FIG. 1 is a diagram showing one example of a manufacturing process of a lithium battery.

FIG. 2 consists of diagrams showing an example of a construction of a lithium battery.

FIG. 3 is a diagram describing Embodiment 1.

FIG. 4 is a diagram describing a detection principle of Embodiment 1.

FIG. 5 consists of diagrams describing Embodiment 2.

FIG. 6 consists of diagrams describing Embodiment 3.

FIG. 7 consists of diagrams describing Embodiment 4.

FIG. 8 is a diagram describing Embodiment 5.

FIG. 9 is a diagram describing Embodiment 6.

FIG. 10 is a diagram describing Embodiment 7.

FIG. 11 is a diagram describing Embodiment 8.

FIG. 12 is a diagram describing Embodiment 9.

FIG. 13 consists of diagrams describing Embodiment 10.

FIG. 14 is a diagram describing another variation of Embodiment 10.

FIG. 15 is a diagram describing Embodiment 11.

FIG. 16 consists of diagrams describing Embodiment 12.

FIG. 17 consists of diagrams describing Embodiment 13.

FIG. 18 is a diagram describing Embodiment 14.

FIG. 19 is a diagram describing Embodiment 15.

FIG. 20 is a diagram describing Embodiment 16.

FIG. 21 consists of diagrams describing Embodiment 17.

FIG. 22 consists of diagrams describing Embodiment 18.

FIG. 23 is a diagram describing Embodiment 19.

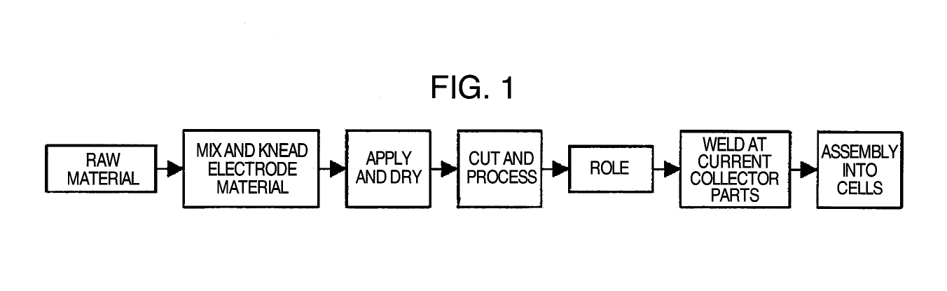

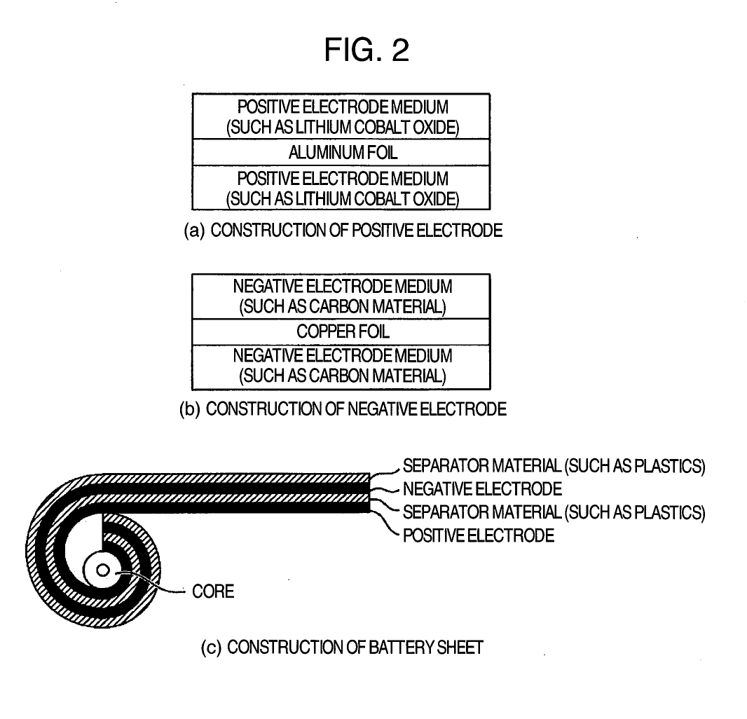

### DESCRIPTION OF EMBODIMENTS

Hereinafter, embodiments are explained by referring to the accompanying drawings.

Incidentally, a plurality of embodiments are explained below and each embodiment may be implemented independently or they may be implemented in combination.

### Embodiment 1

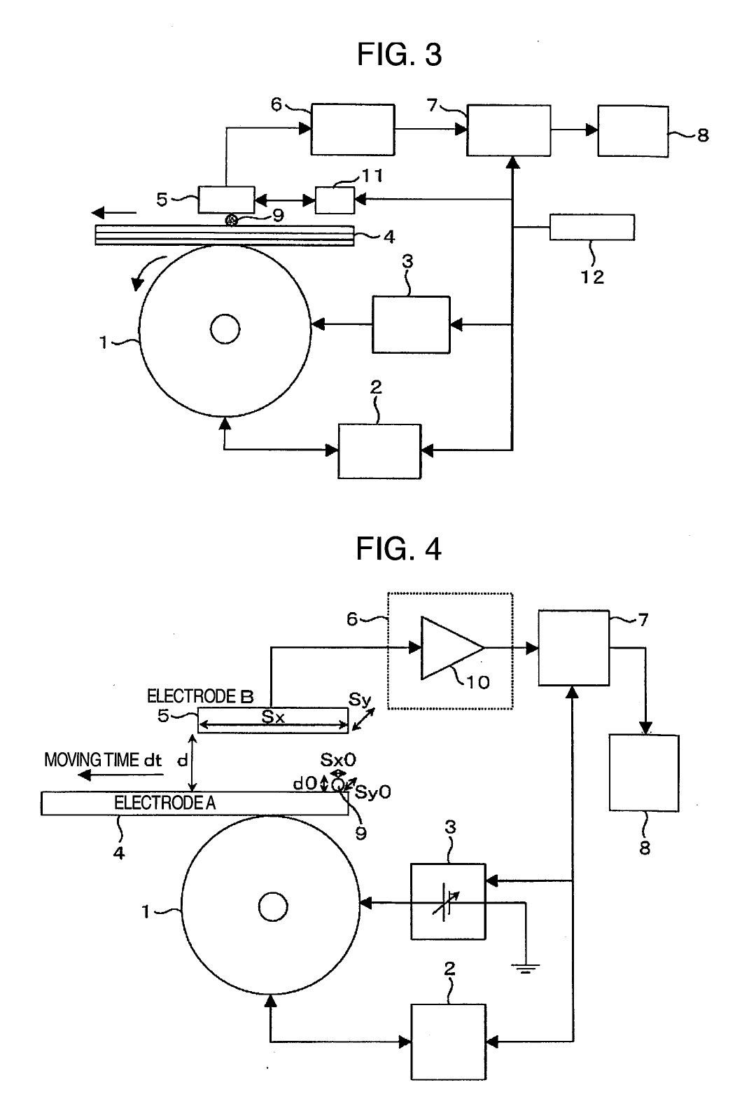

FIG. 3 is a figure showing a configuration of a defect inspection device of Embodiment 1.

As shown in FIG. 3, a roller 1 which moves and transfers a battery sheet 4 is connected to a power supply 3 while a rotation speed (a moving speed of the battery sheet 4) is controlled by a speed control unit 2, which controls the rotation speed of the roller 1.

The roller 1 and the battery sheet 4 are in contact with each other so that they are at the same potential and they and an electrode 5 which is disposed parallel to and away by a certain distance from the battery sheet 4 together form a parallel plate capacitor.

The electrode 5 is equipped with a spacing control unit 11 which adjusts a spacing between the electrodes and is connected to a detection unit 6 that has a current amplification means to amplify a current flowing at the time when an electrostatic capacitance changes by changing the spacing between the electrodes if there is a metallic foreign body 9 on the battery sheet 4 and an I-V conversion means for converting current into voltage.

When a signal from the detection unit 6 is a voltage higher than a defined value, an overall control unit 7 displays a foreign body detection information on a display unit 8.

Further in the overall control unit 7, based on data input by an input unit 12, a voltage control on the power supply 3 and a speed control on the speed control unit 2 for the roller 1 are also performed to control the power supply voltage and the roller rotation speed depending on the size of a metallic foreign body 9 to be detected; further, it moves the electrode 5 in a direction normal to the battery sheet 4 via the spacing control unit 11 to perform position adjustment.

By using the defect inspection device of the present embodiment, the voltage and the moving speed of the object to be inspected can be optimized according to the size of a defect to be detected and it becomes possible to detect defects with high sensitivity without destroying the inspection object while application of high voltage is avoided.

Although the detected current is converted into voltage here in the detection unit 6, existence of a foreign body may be judged with the current as is without performing IV conversion.

Also, while in the present embodiment the detection unit 6 is connected to the electrode 5 and the power supply 3 is connected to the roller 1, the power supply 3 may be connected to the electrode 5 and the detection unit 6 may be connected to the roller 1.

FIG. 4 is a diagram showing a detection principle of the present Embodiment 1.

As shown in FIG. 4, the roller 1, which moves and transfers the battery sheet 4, is connected to the power supply 3 while the rotation speed (the moving speed of the battery sheet 4) is controlled by the speed control unit 2, which controls the rotation speed of the roller 1.

The roller 1 and the battery sheet 4 are in contact with each other so that they are at the same potential and they and the electrode 5 (Electrode B), which is disposed parallel to and away by a certain distance from the battery sheet 4 (Electrode A), together form a parallel plate capacitor.

The size of the electrode 5 is equal to or smaller than the size of the battery sheet 4 both in the longitudinal (Sy) and the lateral (Sx) directions; the electrode 5 generates a change in an electrostatic capacitance by a change in a spacing between the electrodes (d−d0) if there is a metallic foreign body 9 on the battery sheet 4, a current flowing at the time is amplified by a current amplifier 10 in the detection unit 6, and the current is converted into voltage.

When a signal from the detection unit 6 is a voltage higher than a defined value, the overall control unit 7 displays a foreign body detection information on the display unit 8.

Further in the overall control unit 7 a voltage control on the power supply 3 and a speed control on the speed control unit 2 for the roller 1 are also performed to control the power supply voltage and the roller rotation speed depending on the size of a metallic foreign body 9 to be detected.

Here, letting the electrostatic capacitance when there is no foreign body be C, the electrostatic capacitance when there is a foreign body be C0, the permittivity of vacuum be ε, the relative permittivity of the foreign body be εs, the size of the foreign body be Sy0 in the longitudinal direction, Sx0 in the lateral direction, and d0 in the height, and the spacing between the electrodes be d, the amount of change in the electrostatic capacitance ΔC in the present embodiment is expressed as follows.

$$\begin{matrix}[ MATH . 1 ] & \\ \begin{matrix}Δ C = C 0 - C \\ = ( \frac{ɛ s \cdot ɛ \cdot S x 0 \cdot Sy 0}{d - d 0} + \frac{ɛ \cdot ( Sx \cdot Sy - Sx 0 \cdot S y 0 )}{d} ) - \\ \frac{ɛ \cdot Sx \cdot Sy}{d}\end{matrix} & ( MATH . 1 )\end{matrix}$$

Supposing that the power supply voltage is V and that the time during which the metallic foreign body 9 on the battery sheet 4 passes by the electrode 5 is dt, the current I that flows at the moment is given as follows.

$$\begin{matrix}[ MATH . 2 ] & \\ I = \frac{Δ C \cdot V}{dt} & ( MATH . 2 )\end{matrix}$$

As can be seen from the above expressions, since the amount of change in the electrostatic capacitance is determined by the area of the electrode 5, the area of the metallic foreign body 9, the distance between the electrodes, and the height of the foreign body, needless to say by optimizing the size of the electrode 5 and the distance between the electrodes, since the current to be detected depends on the power supply voltage and the moving speed of the battery sheet 4, a metallic foreign body 9 of a desired size can be detected by optimizing the power supply voltage and the moving speed.

Incidentally, the power supply 3 is preferably a DC power; when an AC power is used, an integrator unit, though not shown in the figure, that is synchronous with the cycle of the AC power supply may be provided in the detection unit 6 to detect a change per unit time.

### Embodiment 2

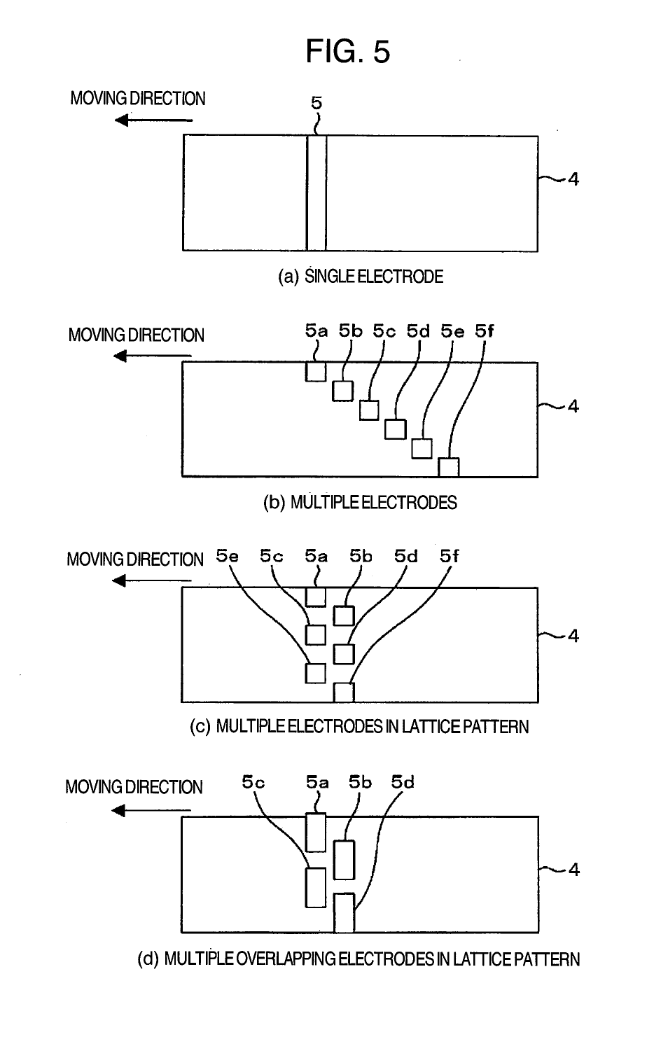

FIG. 5 consists of diagrams showing defect inspection devices of Embodiment 2.

In Embodiment 2, to inspect the entire surface of the battery sheet 4 which is an object to be inspected, an electrode with its length in a direction in a plane parallel to the surface of the battery sheet 4 and perpendicular to the moving direction of the battery sheet 4 equal to or greater than the width of the battery sheet 4 is arranged, as shown in FIG. 5(a).

Also, in order to inspect the entire surface of the battery sheet 4 which is an object to be inspected, a plurality of electrodes 5a-5f with respect to a direction in a plane parallel to the surface of the battery sheet 4 and perpendicular to the moving direction of the battery sheet 4 may be arranged, as shown in FIG. 5(b).

Further, the plurality of electrodes 5a-5f may also be arranged in a lattice pattern, as shown in FIG. 5(c).

Moreover, the plurality of electrodes 5a-5d may also be arranged in a lattice pattern and made to overlap with each other in a direction perpendicular to the moving direction of the battery sheet 4, as shown in FIG. 5(d).

Incidentally, the shape of the electrode 5 may be a quadrangle (a square, a rectangle, a diamond, or a trapezoid), a circle, or a polygon.

### Embodiment 3

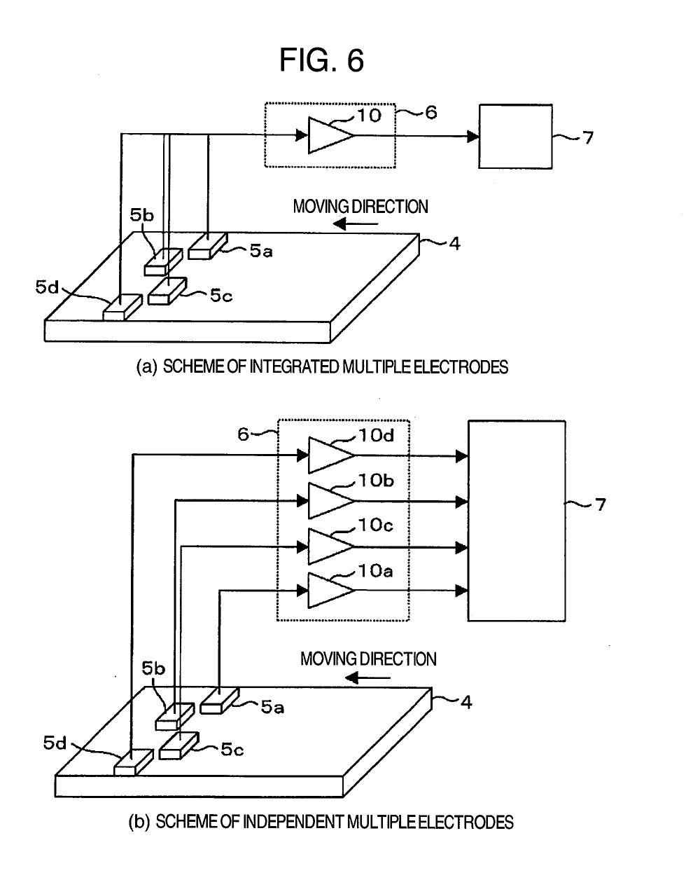

FIG. 6 consists of diagrams showing Embodiment 3.

In Embodiment 3, there is a characteristic in the detection unit for a plurality of electrodes.

In Embodiment 3, signals of a plurality of the electrodes 5a-5d arranged on a plane parallel to the surface of the battery sheet 4 in a direction perpendicular to the moving direction of the battery sheet 4 are integrated together to be input when being input to the current amplifier 10 in the detection unit 6 to inspect the entire surface of the battery sheet 4 which is an object to be inspected, as shown in FIG. 6(a).

Also, signals of a plurality of the electrodes 5a-5d arranged in a direction perpendicular to the moving direction of the battery sheet 4 may be input individually to corresponding current amplifiers 10a-10d in the detection unit 6 to inspect the entire surface of the battery sheet 4 which is an object to be inspected, as shown in FIG. 6(b), so that it becomes possible to recognize at which position on the battery sheet 4 a foreign body exists.

### Embodiment 4

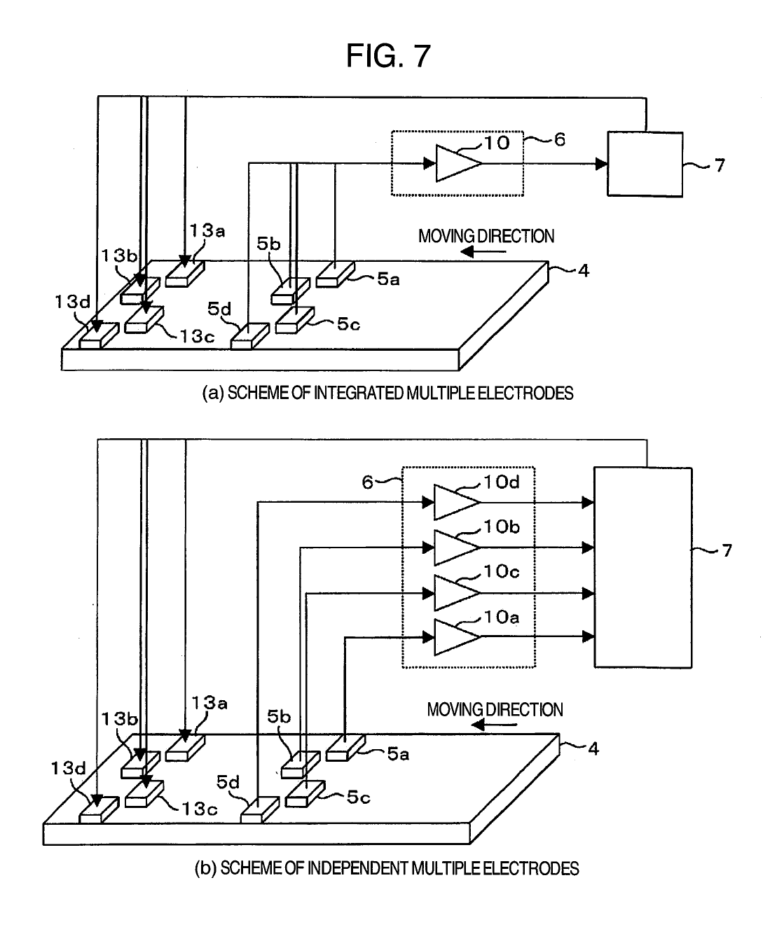

FIG. 7 consists of diagrams describing Embodiment 4.

Embodiment 4 has a defect marking function.

FIG. 7(a) is a configuration in which signals of a plurality of the electrodes 5a-5d arranged on a plane parallel to the surface of the battery sheet 4 in a direction perpendicular to the moving direction of the battery sheet 4 are integrated to be input when being input to the current amplifier 10 in the detection unit 6 to inspect the entire surface of the battery sheet 4 which is an object to be inspected.

FIG. 7(b) is a configuration in which signals of a plurality of the electrodes 5a-5d arranged on a plane parallel to the surface of the battery sheet 4 in a direction perpendicular to the moving direction of the battery sheet 4 are input individually to corresponding current amplifiers 10a-10d in the detection unit 6 to inspect the entire surface of the battery sheet 4 which is an object to be inspected.

The battery sheet 4, for which presence of foreign bodies is inspected by the plurality of the electrodes 5a-5d, respectively, is transferred to a position where a plurality of defect marking function units 13a-13d exist and, if foreign bodies exist, the battery sheet 4 is marked so that the portions are not to be used in subsequent processes.

Here, for the defect marking function units 13a-13d, devices used for printing such as inkjet may be used.

Incidentally, although in the present Embodiment 4 descriptions are given for a plurality of the electrodes 5a-5d and a plurality of the defect marking function units 13a-13d, a combination of a single electrode 5 and a single defect marking unit 13 may work; moreover, needless to say, it may be a combination of a plurality of electrode 5a-5d and a plurality of defect marking function units 13a-13d with a single electrode 5 and a single defect marking function 13.

### Embodiment 5

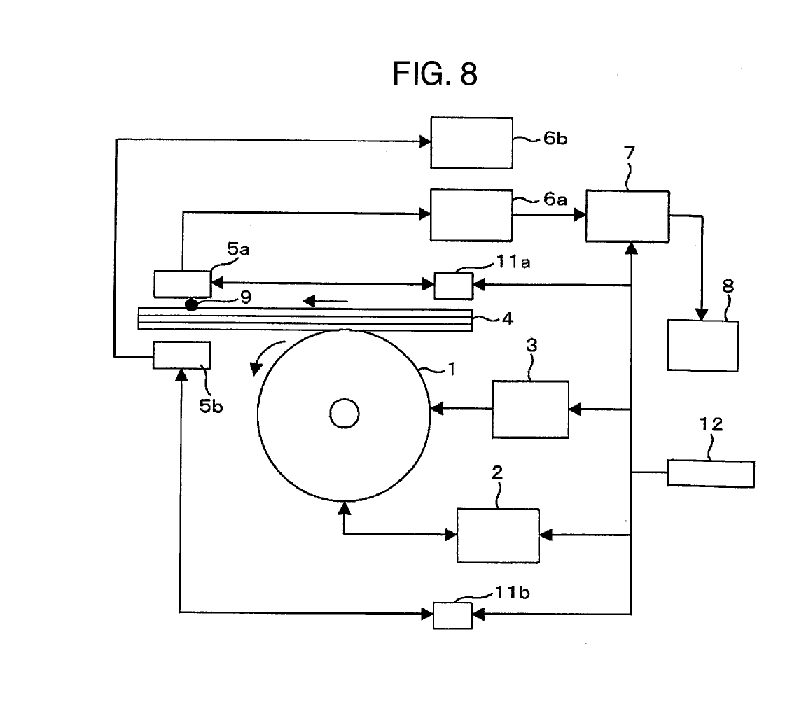

FIG. 8 is a diagram describing a configuration of Embodiment 5.

In the present Embodiment 5, electrodes 5a, 5b are provided on the front and back sides of the battery sheet 4, which is an object to be inspected, to detect changes in electrostatic capacitances by detection units 6a, 6b corresponding to the respective electrodes, as shown in FIG. 8.

Further, individual electrodes are equipped with spacing control units 11a, 11b to adjust spacings to the inspection object.

With this configuration, both front and back sides of the inspection object can be inspected simultaneously.

### Embodiment 6

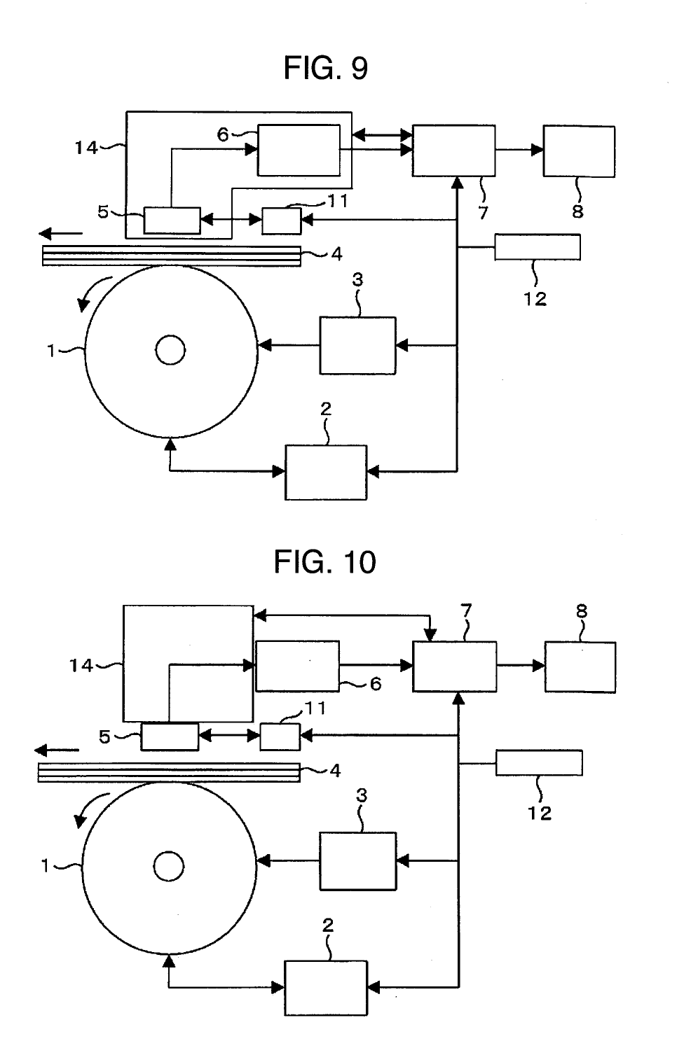

FIG. 9 is a diagram describing a configuration of Embodiment 6.

Embodiment 6 is characterized by having a function to cool the defect inspection device.

As shown in FIG. 9, the roller 1, which moves and transfers a battery sheet 4, is connected to the power supply 3 while the rotation speed (the moving speed of the battery sheet 4) is controlled by the speed control unit 2, which controls the rotation speed of the roller 1.

The roller 1 and the battery sheet 4 are in contact with each other so that they are at the same potential and they and the electrode 5, which is disposed parallel to and away by a certain distance from the battery sheet 4, together form a parallel plate capacitor.

The electrode 5 is equipped with a spacing control unit 11 which adjusts a spacing between the electrodes and is connected to the detection unit 6 that has a current amplification means to amplify a current flowing at the time when an electrostatic capacitance changes by changing a spacing between the electrodes if there is a metallic foreign body 9 on the battery sheet 4 and an I-V conversion means for converting current into voltage.

When a signal from the detection unit 6 is a voltage higher than a defined value, the overall control unit 7 displays a foreign body detection information on the display unit 8.

Further in the overall control unit 7, based on data input by the input unit 12, a voltage control on the power supply 3 and a speed control on the speed control unit 2 for the roller 1 are also performed to control the power supply voltage and the roller rotation speed depending on the size of a metallic foreign body 9 to be detected; further, it moves the electrode 5 in a direction normal to the battery sheet 4 via the spacing control unit 11 to perform position adjustment.

Moreover, by enclosing from the electrode 5 to the detection unit 6 with a cooling mechanism unit 14 and cooling, noise can be reduced, thereby making it possible to detect even smaller changes in an electrostatic capacitance.

Here, as a cooling medium of the cooling mechanism unit 14, He₂ (helium, 4.22K, −276.93° C.) and N₂ (nitrogen, 77.36K, −195.79° C.), which is less expensive but higher in temperature than He₂, may be used with consideration of device performance and the costs.

### Embodiment 7

FIG. 10 is a diagram describing a configuration of Embodiment 7.

As shown in FIG. 10, the roller 1, which moves and transfers a battery sheet 4, is connected to the power supply 3 while the rotation speed (the moving speed of the battery sheet 4) is controlled by the speed control unit 2, which controls the rotation speed of the roller 1.

The roller 1 and the battery sheet 4 are in contact with each other so that they are at the same potential and they and the electrode 5, which is disposed parallel to and away by a certain distance from the battery sheet 4, together form a parallel plate capacitor.

The electrode 5 is equipped with the spacing control unit 11 which adjusts a spacing between the electrodes and is connected to the detection unit 6 that has a current amplification means to amplify a current flowing at the time when an electrostatic capacitance changes by changing a spacing between the electrodes if there is a metallic foreign body 9 on the battery sheet 4 and an I-V conversion means for converting current into voltage.

When a signal from the detection unit 6 is a voltage higher than a defined value, the overall control unit 7 displays a foreign body detection information on the display unit 8.

Further in the overall control unit 7, based on data input by the input unit 12, a voltage control on the power supply 3 and a speed control on the speed control unit 2 for the roller 1 are also performed to control the power supply voltage and the roller rotation speed depending on the size of a metallic foreign body 9 to be detected; further, it moves the electrode 5 in a direction normal to the battery sheet 4 via the spacing control unit 11 to perform position adjustment.

Moreover, by enclosing from a signal transmission path from the electrode 5 to the detection unit 6 with a cooling mechanism unit 14 and cooling, noise can be reduced before the current is amplified, thereby making it possible to detect even smaller changes in an electrostatic capacitance.

Here, as a cooling medium of the cooling mechanism unit 14, He₂ (helium, 4.22K, −276.93° C.) and N₂ (nitrogen, 77.36K, −195.79° C.), which is less expensive but higher in temperature than He₂, may be used with consideration of device performance and the costs.

Incidentally, although it is not shown, a superconductive material may be used in the signal transmission path from the electrode 5 to the detection unit 6 so that noise may be reduced by transmitting detected signals to the detection unit 6 at a low temperature.

Although in the foregoing respective embodiments explanations are given on the inspection of battery sheets, the defect inspection method of the present invention can be applied by partially replacing the roller to increase an area parallel to the electrode when the object to be inspected is even an insulating material and the defects to be detected are metallic, even without saying that the defect inspection method of the present invention can be applied when the object to be inspected is a metal or a metallic film and the defects to be detected are metallic.

### Embodiment 8

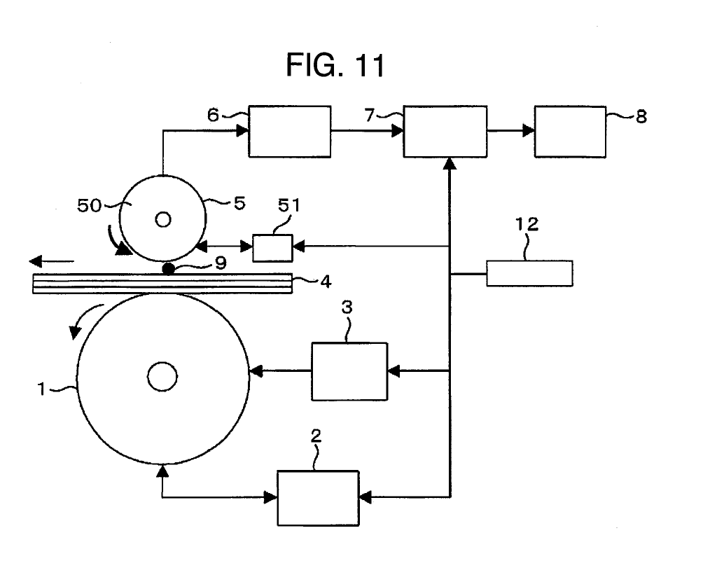

FIG. 11 is a diagram showing a configuration of Embodiment 8.

As shown in FIG. 11, the roller 1, which moves and transfers the battery sheet 4, is connected to the power supply 3 while the rotation speed (the moving speed of the battery sheet 4) is controlled by the speed control unit 2, which controls the rotation speed of the roller 1.

The roller 1 and the battery sheet 4 are in contact with each other so that they are at the same potential, and they and the electrode 5 provided uniformly on a rotor 50 rotating in a direction opposite to the moving direction of the battery sheet 4, which is disposed parallel to and away by a certain distance from the battery sheet 4, together form a parallel plate capacitor.

The electrode 5 is equipped with an electrode control unit 51 which adjusts a spacing between the electrodes and controls the rotating speed of the rotor and is connected to the detection unit 6 that has a current amplification means to amplify a current flowing at the time when an electrostatic capacitance changes by changing the spacing between the electrodes if there is a metallic foreign body 9 on the battery sheet 4 and an I-V conversion means for converting current into voltage.

When a signal from the detection unit 6 is a voltage higher than a defined value, the overall control unit 7 displays a foreign body detection information on the display unit 8.

Further in the overall control unit 7, based on data input by the input unit 12, a voltage control on the power supply 3, a speed control on the speed control unit 2 for the roller 1, and a rotation speed control on the rotor 50 equipped with the electrode 5 are performed to control the power supply voltage, the roller rotation speed, and the rotor rotation speed depending on the size of a metallic foreign body 9 to be detected; further, it moves the electrode 5 in a direction normal to the battery sheet 4 via the electrode control unit 51 to perform position adjustment.

In Embodiment 8, the voltage, the moving speed of the object to be inspected, and the rotation speed of the rotor equipped with the electrode can be optimized according to the size of a defect to be detected and it becomes possible to detect defects with high sensitivity without destroying the inspection object while application of high voltage is avoided.

Although the detected current is converted into voltage here in the detection unit 6, existence of a foreign body may be judged with the current as is without performing IV conversion.

Also, while in the present Embodiment 8 the detection unit 6 is connected to the electrode 5 and the power supply 3 is connected to the roller 1, the power supply 3 may be connected to the electrode 5 and the detection unit 6 may be connected to the roller 1.

Further, as shown in FIG. 9 or FIG. 10, a cooling mechanism unit may be provided in the detection unit 6 or between the electrode 5 and the detection unit 6 and, furthermore, it goes without saying that the electrodes 5 may be provided on both the front and back sides of the object to be inspected as shown in FIG. 8.

### Embodiment 9

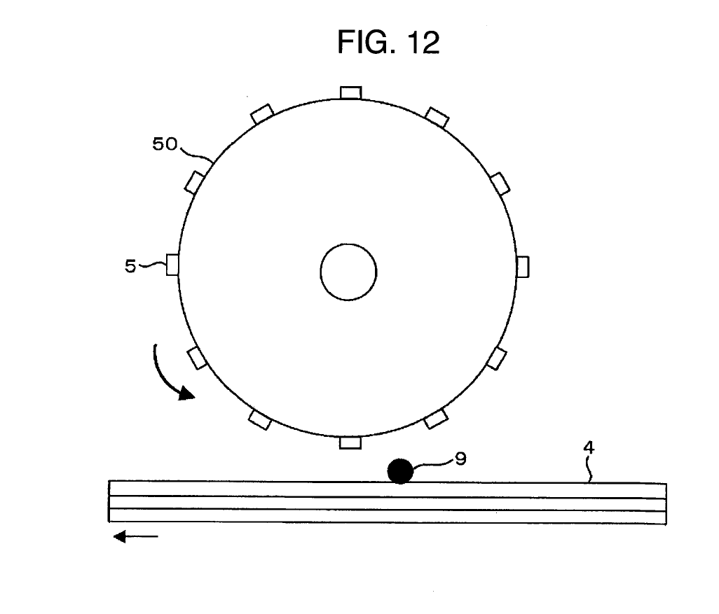

FIG. 12 is a figure showing a configuration of Embodiment 9.

Since a shorter detection time results in a higher sensitivity as shown in MATH. 2, enhancement of the sensitivity can be designed by arranging electrodes 5 on the rotor 50 at fixed intervals as shown in FIG. 12 rather than disposing the electrodes 5 uniformly on the rotor 50.

Incidentally, as for a method of signal transmission from the electrodes 5 to the detection unit 6, a contact scheme with brushes, a non-contact scheme with photocouplers, or the like may be used; when solar cells are used as a power supply for the photocouplers, it can be configured as a completely non-contact.

### Embodiment 10

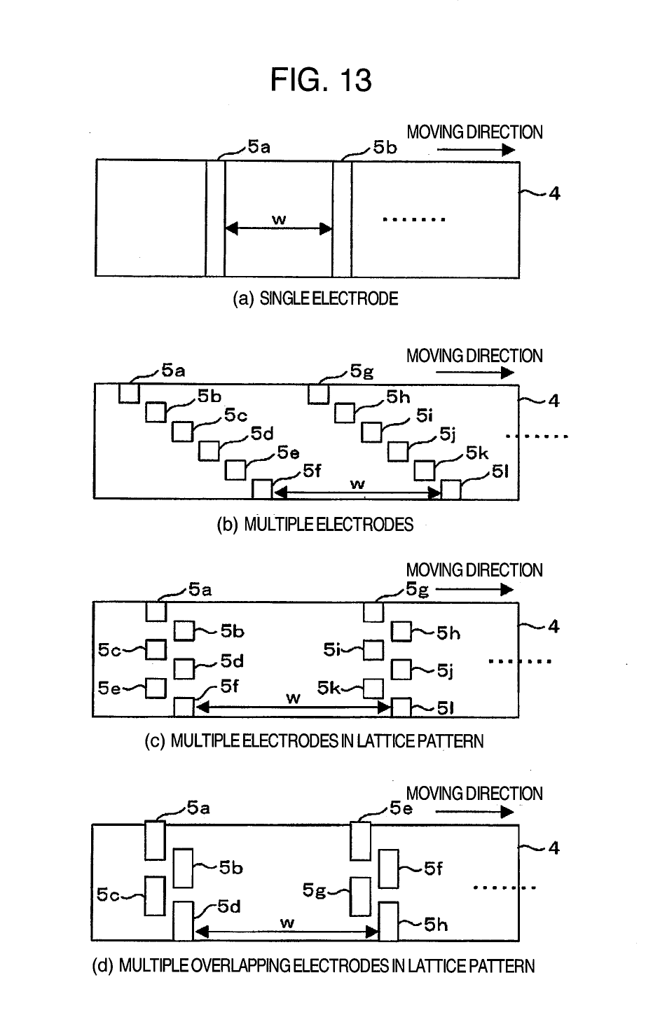

FIG. 13 consists of diagrams showing configurations of Embodiment 10.

In Embodiment 10, when the electrodes 5 are arranged on the rotor 50, to inspect the entire surface of the battery sheet 4 which is an object to be inspected, electrodes with their lengths in a direction in a plane parallel to the surface of the battery sheet 4 and perpendicular to the moving direction of the battery sheet 4 equal to or greater than the width of the battery sheet 4 are arranged at a certain interval (w), as shown in FIG. 13(a).

Also, in order to inspect the entire surface of the battery sheet 4 which is an object to be inspected, a plurality of electrodes 5a-5l with respect to a direction in a plane parallel to the surface of the battery sheet 4 and perpendicular to the moving direction of the battery sheet 4 may be arranged at a certain interval (w), as shown in FIG. 13(b).

Further, the plurality of electrodes 5a-5l may also be arranged in a lattice pattern at a certain interval (w), as shown in FIG. 13(c).

Moreover, the plurality of electrodes 5a-5h may also be arranged in a lattice pattern at a certain interval (w) and made to overlap with each other in a direction perpendicular to the moving direction of the battery sheet 4, as shown in FIG. 13(d).

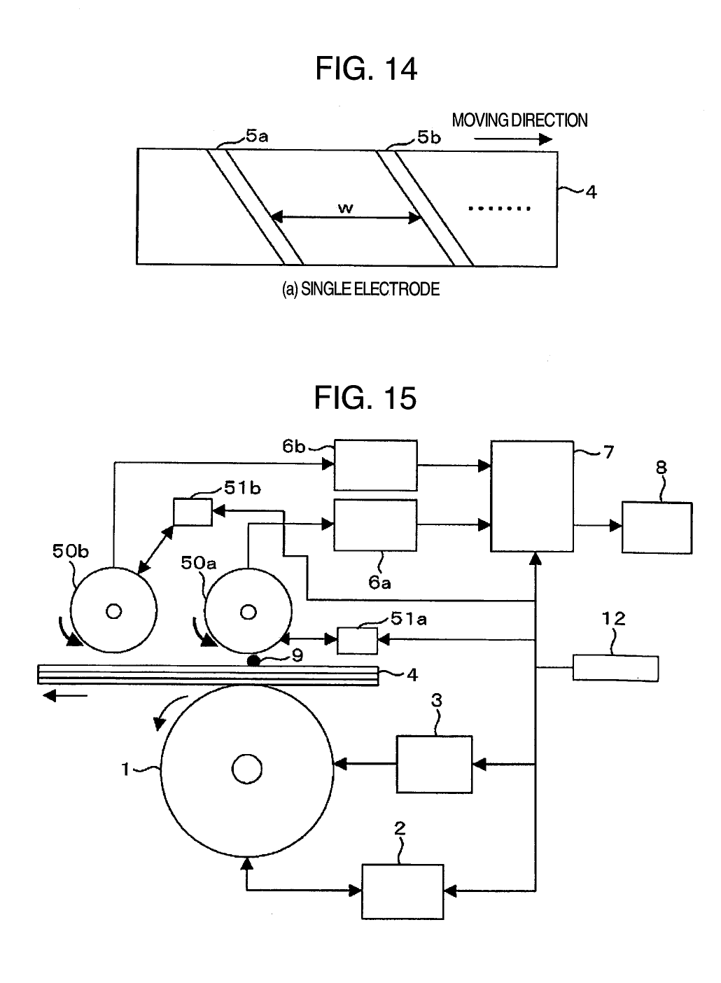

Besides, FIG. 14 is a diagram showing another variation of Embodiment 10.

As shown in FIG. 14, electrodes with their lengths in a direction perpendicular to the moving direction of the battery sheet 4 equal to or greater than the width of the battery sheet 4 may be arranged at a certain interval (w) obliquely on the surface of the battery sheet 4.

Incidentally, the shape of the electrode 5 may be a quadrangle (a square, a rectangle, a diamond, or a trapezoid), a circle, or a polygon.

### Embodiment 11

FIG. 15 is a diagram showing a configuration of Embodiment 11.

As shown in FIG. 15, the roller 1, which moves and transfers the battery sheet 4, is connected to the power supply 3 while the rotation speed (the moving speed of the battery sheet 4) is controlled by the speed control unit 2, which controls the rotation speed of the roller 1. The roller 1 and the battery sheet 4 are in contact with each other so that they are at the same potential, and they and the electrodes 5 provided at certain intervals on a plurality of rotors 50a, 50b rotating in a direction opposite to the moving direction of the battery sheet 4, which are disposed parallel to and away by certain distances from the battery sheet 4, together form parallel plate capacitors.

The electrodes 5 are equipped with a plurality of electrode control units 51a, 51b which adjust spacings between the electrodes and control the rotation speeds of the plurality of the rotors and are connected to a plurality of detection units 6a, 6b which have current amplification means to amplify currents flowing at the time when electrostatic capacitances change by changing spacings between the electrodes if there is a metallic foreign body 9 on the battery sheet 4 and I-V conversion means for converting currents into voltages.

When signals from the detection units 6a, 6b are voltages higher than a defined value, the overall control unit 7 displays a foreign body detection information on the display unit 8.

Further in the overall control unit 7, based on data input by the input unit 12, a voltage control on the power supply 3, a speed control on the speed control unit 2 for the roller 1, and rotation speed controls on the plurality of the rotors 50a, 50b equipped with the electrodes 5 are performed to control the power supply voltage, the roller rotation speed, and the rotor rotation speeds depending on the size of a metallic foreign body 9 to be detected; further, it moves the electrodes 5 in a direction normal to the battery sheet 4 via the respective electrode control units 51a, 51b to perform position adjustment.

Moreover, as for rotations of the rotors, the rotation start positions or phases of the plurality of the rotors 50a, 50b are controlled by the overall control unit 7 in order to inspect the same position on the battery sheet 4 at different phases of the rotors.

In Embodiment 11, the voltage, the moving speed of the object to be inspected, and the rotation speeds of the rotors equipped with the electrodes can be optimized according to the size of a defect to be detected and it becomes possible to detect defects with high sensitivity without destroying the inspection object while application of high voltage is avoided.

Also, even when a defect passes between the electrodes 5 arranged at a certain interval, the defect can still be detected by the electrodes on a rotor rotating at a different phase so that it prevents overlooking and, together, enables defect detection at high sensitivity.

Although the detected current is converted into voltage here in the detection units 6a, 6b, existence of a foreign body may be judged with the current as is without performing IV conversion.

Also, while in the present embodiment the detection units 6a, 6b are connected to the electrodes 5 and the power supply 3 is connected to the roller 1, the power supply 3 may be connected to the electrodes 5 and the detection units 6a, 6b may be connected to the roller 1.

### Embodiment 12

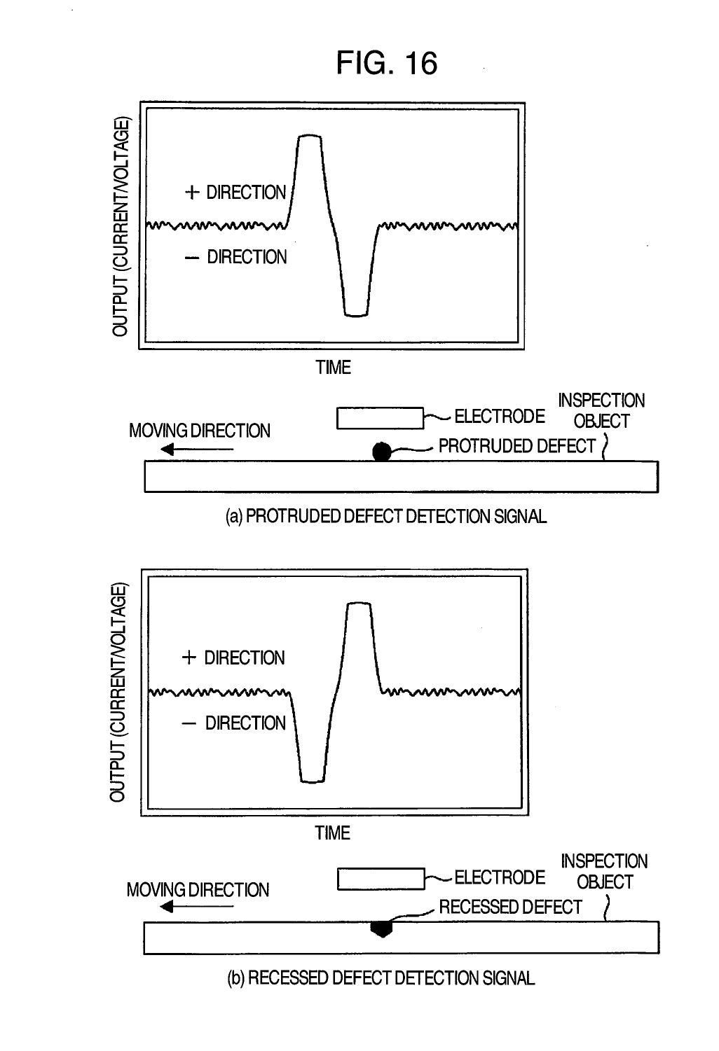

FIG. 16 consists of diagrams showing Embodiment 12.

When there is a protruded defect on the object to be inspected as shown in FIG. 16(a), the distance between the electrode and the inspection object becomes shorter first to increase the electrostatic capacitance so that the output swings to the positive direction and, as the defect passes by the electrode, the electrostatic capacitance decreases to cause to swing to the negative direction.

On the contrary, when there is a recessed defect on the object to be inspected, the distance between the electrode and the inspection object becomes greater first to decrease the electrostatic capacitance so that the output swings to the negative direction as shown in FIG. 16(b) and, as the defect passes by the electrode, the electrostatic capacitance increases to cause to swing to the positive direction.

Therefore, by checking whether in the positive or negative direction the defect detection output swings first the type of the defect (recessed or protruded) can be judged.

### Embodiment 13

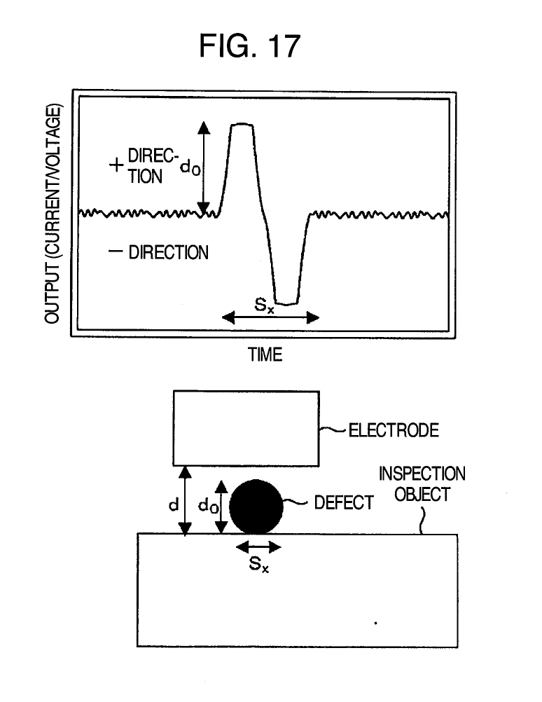

FIG. 17 consists of diagrams describing Embodiment 13.

Since the detection output becomes larger in proportion to the height d0 of the defect and a time of detection signal variation becomes longer in proportion to the size Sx of the defect as shown in FIG. 17, it become possible to judge the size of the defect from the output value of the defect detection and the time of the detection output variation.

### Embodiment 14

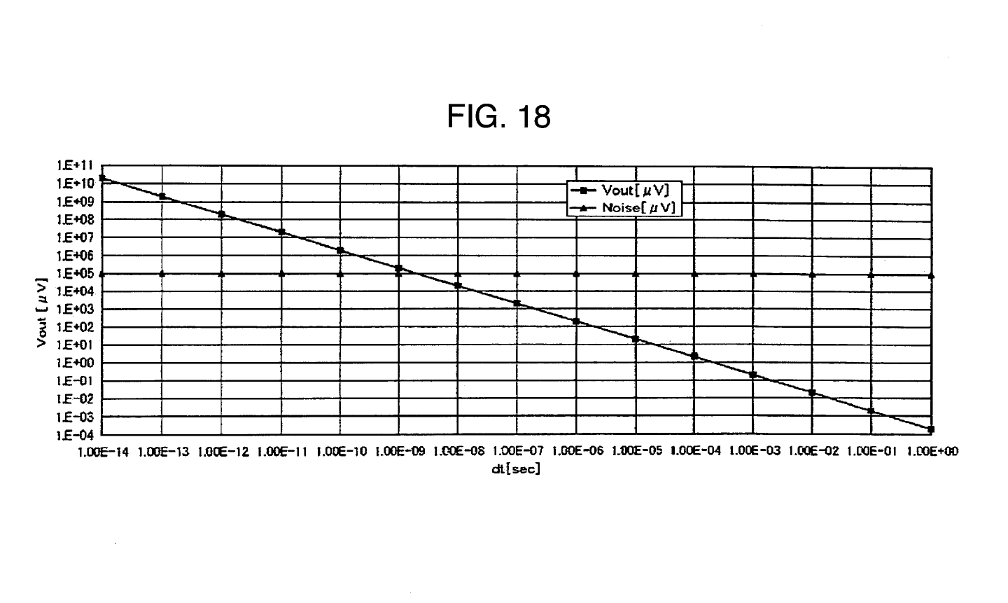

FIG. 18 is a diagram describing Embodiment 14 and a diagram showing an example of the relationship between a defect detection output and a moving time.

As shown in FIG. 18, an inversely proportional relationship between the defect detection output and the moving time holds.

Therefore, an optimal moving time (moving speed) can be set from the size of the defect to be detected and a system noise.

### Embodiment 15

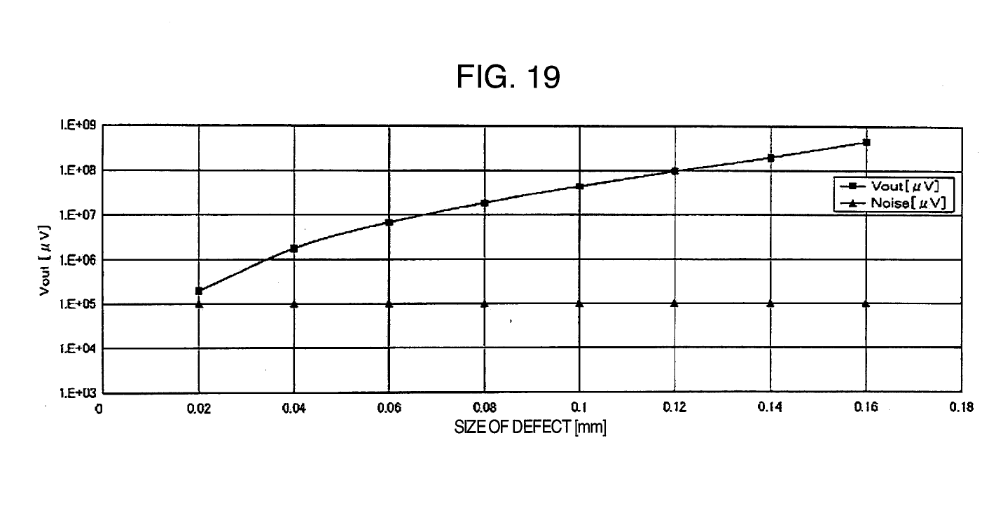

FIG. 19 is a diagram describing Embodiment 15 and a diagram showing an example of the relationship between a defect size and a detection output.

As shown in FIG. 19, a proportional relationship between the defect size (height) and the defect detection output holds. The size of the defect can, therefore, be determined from the defect detection output.

### Embodiment 16

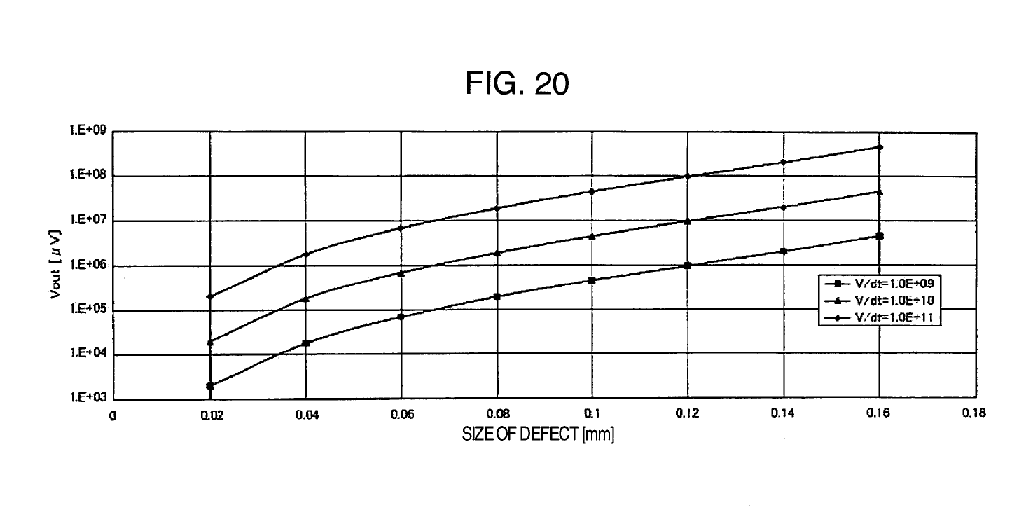

FIG. 20 is a diagram describing Embodiment 16 and a diagram showing another example of the relationship between the defect size and the detection output.

Since, as explained earlier, a proportional relationship between the defect size (height) and the defect detection output holds as shown in FIG. 20 and the defect detection output is proportional to V/dt in the aforementioned MATH. 2, it is possible to detect defects and determine the sizes of the defects by setting V (voltage) and dt (moving speed) to optimal values according to the size of defects to be detected.

### Embodiment 17

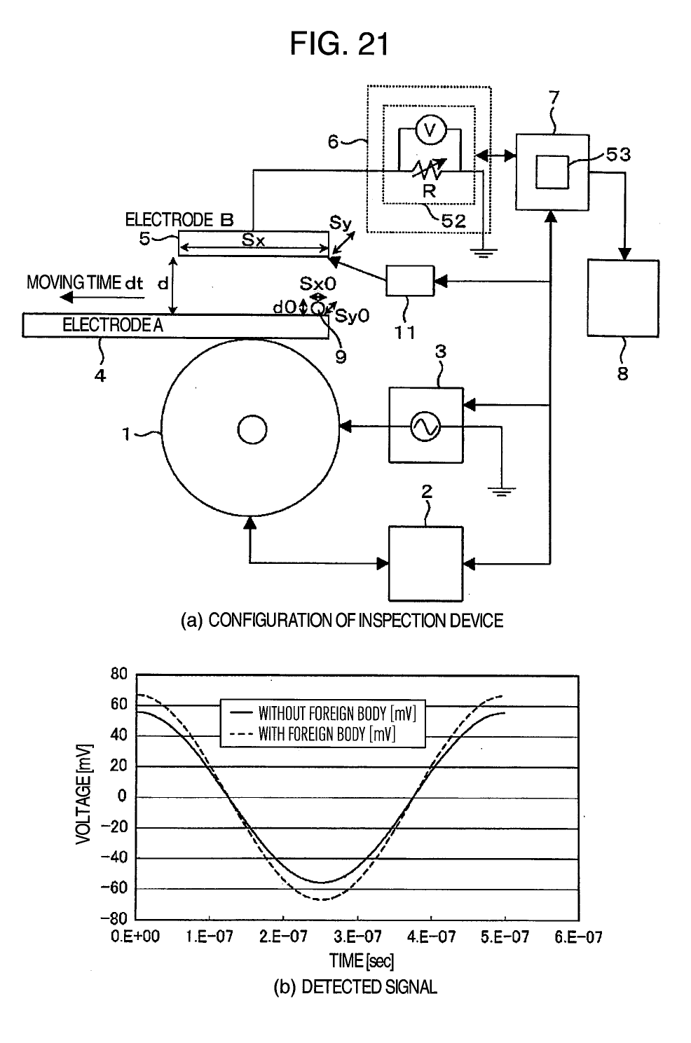

FIG. 21 consists of diagrams describing a configuration of Embodiment 17.

As shown in FIG. 21(a), the roller 1 which moves and transfers the battery sheet 4 is connected to an AC power supply 53 while the rotation speed (the moving speed of the battery sheet 4) is controlled by the speed control unit 2, which controls the rotation speed of the roller 1.

The roller 1 and the battery sheet 4 are in contact with each other so that they are at the same potential and they and the electrode 5, which is disposed parallel to and away by a certain distance from the battery sheet 4 together form a parallel plate capacitor.

The electrode 5 is equipped with a spacing control unit 11 which adjusts a spacing between the electrodes and is connected to a detection unit 6 that has a current amplification means to amplify a current flowing at the time when an electrostatic capacitance changes by changing a spacing between the electrodes if there is a metallic foreign body 9 on the battery sheet 4 and a voltage detection unit 52.

In the voltage detection unit 52 a voltage across a resistor R is measured. The overall control unit 7 compares a signal from the detection unit 6 and a signal from the power supply in a comparator unit 54 and, when the difference is greater than a defined value, a foreign body detection information is displayed on the display unit 8.

Further in the overall control unit 7, based on data input by the input unit 12, voltage and cycle controls on the AC power supply 53, a speed control on the speed control unit 2 for the roller 1, and a resistance control on the voltage detection unit 52 are also performed to control the power supply voltage, the power supply cycle, and the roller rotation speed and to optimize the resistance of the voltage detection unit 52 depending on the size of a metallic foreign body 9 to be detected; further, it moves the electrode 5 in a direction normal to the battery sheet 4 via the spacing control unit 11 to perform position adjustment.

With Embodiment 17, the voltage and cycle of the AC power supply 53 and the resistance of the voltage detection unit 52 can be optimized according to the size of a defect to be detected and it becomes possible to detect defects with high sensitivity without destroying the inspection object while application of high voltage is avoided.

Although voltage is detected here in the detection unit 6, existence of a foreign body may be judged by detecting a current.

Also, while in the present embodiment the detection unit 6 is connected to the electrode 5 and the power supply 3 is connected to the roller 1, the power supply 3 may be connected to the electrode 5 and the detection unit 6 may be connected to the roller 1.

Moreover, although in the present embodiment the AC power supply 53 and the detected voltage are compared with each other, an output when no defect is present may be stored in a memory in the overall control unit 7 and compared with the detected voltage as shown in FIG. 21(b).

Further, as shown in FIG. 9 or FIG. 10, a cooling mechanism unit may be provided in the detection unit 6 or between the electrode 5 and the detection unit 6 and, furthermore, it goes without saying that the electrodes 5 may be provided on both the front and back sides of the object to be inspected as shown in FIG. 8.

Here, letting the electrostatic capacitance be C, the resistance of the voltage detection unit 52 be R, time be t, the cycle of the AC power supply 53 be f, and the voltage be V×sin(2πft), the current I flowing through the resistor of the voltage detection unit 52 in Embodiment 17 is given as follows.

$$\begin{matrix}[ MATH . 3 ] & \\ I = \frac{V}{\sqrt{{R}^{2} + {( \frac{1}{2 π fC} )}^{2}}} \cdot sin ( 2 π f t + {tan}^{- 1} ( \frac{1}{2 π fCR} ) ) . & ( MATH . 3 )\end{matrix}$$

Also, the voltage across the resistor R detected by the voltage detection unit 52, V_{R}, at this time is expressed as follows.

[MATH. 4]

V_{R}=R·I. (MATH. 4)

As can be seen from the above expressions, since the detected voltage at the voltage detection unit 52 due to changes in the electrostatic capacitance depends on the resistance of the voltage detection unit 52 and the voltage and the cycle of the AC power supply 53, needless to say by optimizing the size of the electrode 5 and the distance between the electrodes, a metallic foreign body 9 of a desired size can be detected by optimizing the voltage and the cycle of the AC power supply and the resistance of the voltage detection unit 52.

In other words, by controlling the resistance of the voltage detection unit 52 and the voltage and the cycle of the AC power supply 53, a metallic foreign body 9 of a desired size can be detected.

Or, in another expression, the control of the voltage and the cycle of the AC power supply and of the resistance of the voltage detection unit 52 enables the detection of a metallic foreign body 9 of a desired size.

### Embodiment 18

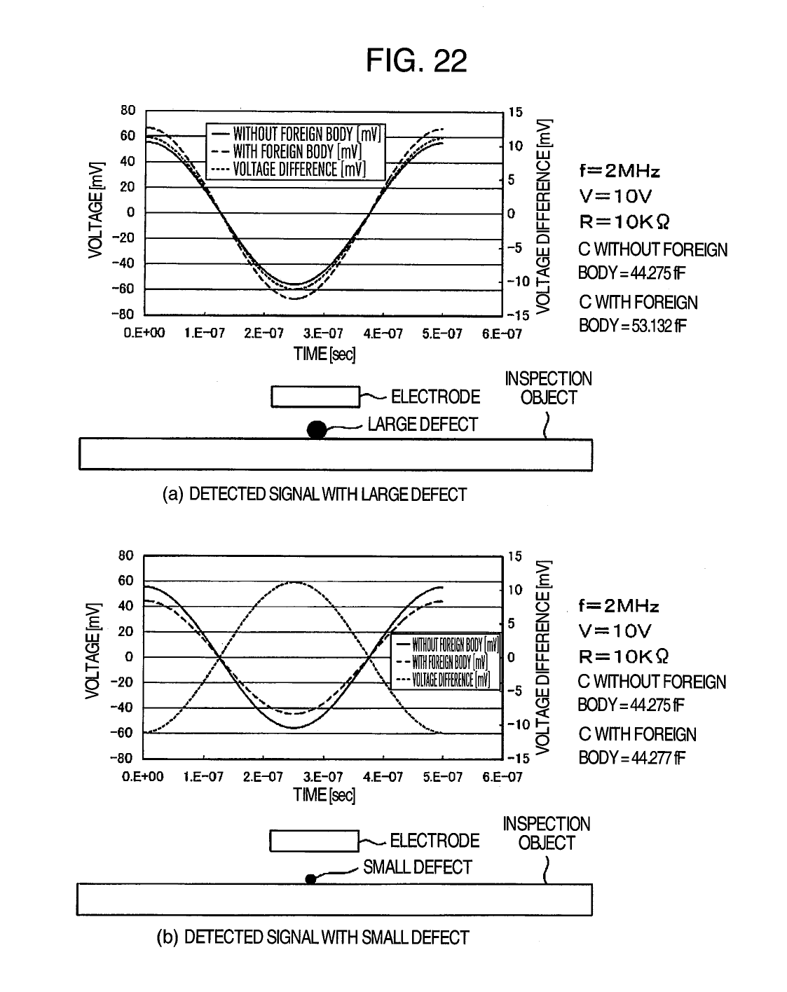

FIG. 22 consists of diagrams describing Embodiment 18.

Under the conditions of the present embodiment, when a large defect exists on the object to be inspected, a detected signal and a difference of detected signals between with and without the defect are in phase as shown in FIG. 22(a); when a small defect exists on the inspected object, however, a detected signal and a difference of detected signals between with and without the defect are out of phase by 180 degrees as shown in FIG. 22(b).

Therefore, by checking the phases of the detected signals and of the difference between with and without the defect, it becomes possible to determine the kind and the size of the defect.

### Embodiment 19

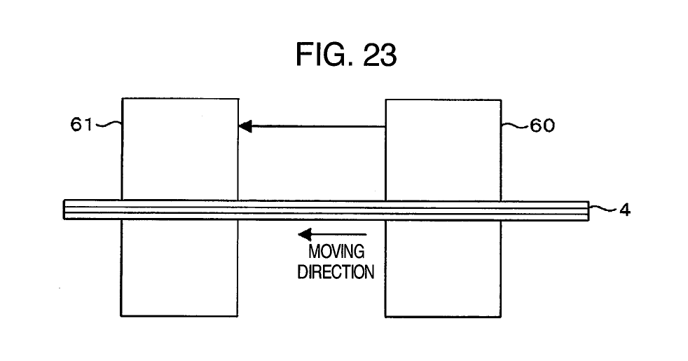

FIG. 23 is a diagram describing Embodiment 19.

By sending information on defects detected by a defect inspection device 60 to a cutting device 61 of the battery sheet 4 as shown in FIG. 23, only those portions with no defects can be automatically selected.

Although in the foregoing embodiments explanations are given on the inspection of the battery sheets, the defect inspection method of the present invention can be applied by partially replacing the roller to increase an area parallel to the electrode when the object to be inspected is even an insulating material and the defects to be detected are metallic, even without saying that the defect inspection method of the present invention can be applied when the object to be inspected is a metal or a metallic film and the defects to be detected are metallic.

### REFERENCE SIGNS LIST

1 . . . roller;
2 . . . speed control unit;
3 . . . power supply;
4 . . . object to be inspected (battery sheet);
5 . . . electrode;
6 . . . detection unit;
7 . . . overall control unit;
8 . . . display unit;
9 . . . metallic foreign body;
10 . . . current amplifier;
11 . . . spacing control unit;
12 . . . input unit;
13 . . . defect marking function unit;
14 . . . cooling mechanism unit;
50 . . . rotor;
51 . . . electrode control unit;
52 . . . voltage detection unit;
53 . . . AC power supply;
54 . . . comparator unit;
60 . . . defect inspection device;
61 . . . cutting device.

1. An inspection device to inspect a defect of an object to be inspected, comprising:
a transfer unit to transfer the object to be inspected;
a first electrode and a second electrode arranged to put the object to be inspected therebetween;
a power supply connected to the first electrode;
a transfer speed control unit to control a transfer speed of the object to be inspected;
a current detection unit connected to the second electrode to detect a current generated due to a change in an electrostatic capacitance formed between the first electrode and the second electrode; and
a defect detection unit to detect a defect based on the current.

2. The inspection device according to claim 1, wherein the power supply is a DC power supply.

3. The inspection device according to claim 1, further comprising:
a spacing control unit to control a spacing between the first electrode and the second electrode.

4. The inspection device according to claim 1, further comprising:
a voltage control unit to control a voltage of the power supply.

5. The inspection device according to claim 1, further comprising:
an amplifier unit to amplify the current; and
an I-V conversion unit to convert the amplified current into a voltage;
wherein the defect detection unit detects a defect based on the converted voltage.

6. The inspection device according to claim 1, wherein a plurality of the first electrodes and a plurality of the second electrodes are arranged in a direction parallel to a surface of the object to be inspected.

7. The inspection device according to claim 6, wherein the first electrodes and the second electrodes are arranged in a lattice pattern.

8. The inspection device according to claim 6, wherein the first electrodes and the second electrodes are arranged in a direction perpendicular to a direction of transfer of the object to be inspected.

9. The inspection device according to claim 1, further comprising:
a marking unit to mark a position of the defect.

10. The inspection device according to claim 1, further comprising:
a cooling unit to cool the second electrode and the current detection unit.

11. The inspection device according to claim 1, wherein the second electrode is a rotating electrode that rotates in a direction opposite to a direction in which the object to be inspected is transferred.

12. The inspection device according to claim 11, wherein a plurality of the rotating electrodes are arranged uniformly or at a certain interval on a rotating body.

13. The inspection device according to claim 12, wherein the plurality of the rotating electrodes arranged at a certain interval on the rotating body are arranged in a lattice pattern on the rotating body.

14. The inspection device according to claim 13,
wherein the plurality of the rotating electrodes are arranged at a certain interval on the rotating body; and
wherein rotation start positions or phases of electrode positions of the rotating electrodes are controlled so that a same position on the object to be inspected can be inspected at different phases.

15. The inspection device according to claim 1, wherein the defect detection unit determines a kind and a size of a defect from a polarity, an output value, and a detection width of a detected signal.

16. The inspection device according to claim 1, wherein the power supply is an AC power supply.

17. The inspection device according to claim 16, wherein the current detection unit comprises a voltage detection unit.

18. The inspection device according to claim 17, wherein a voltage and a cycle of the AC power supply and a resistance of a voltage detection unit are controlled.

19. The inspection device according to claim 18, wherein the defect detection unit determines a kind and a size of a defect from a phase and an output value of a detected signal.
